(19) United States
(12) Patent Application Publication
(10) Pub. No.: US 2012/0326563 A1
(43) Pub. Date: Dec. 27, 2012

(54) ULTRASONIC SENSOR AND METHOD OF MANUFACTURING THE SAME

(76) Inventors: Boum Seock Kim, Gyeonggi-do (KR); Sung Kwon Wi, Seoul (KR); Eun Tae Park, Gyeonggi-do (KR)

(21) Appl. No.: 13/462,756

(22) Filed: May 2, 2012

(30) Foreign Application Priority Data
Jun. 22, 2011 (KR) 10-2011-0060743

(51) Int. Cl. H01L 41/04; B29C 45/14

(52) U.S. Cl. 310/315; 156/245

(57) ABSTRACT

Disclosed herein are an ultrasonic sensor and a method of manufacturing the same. The ultrasonic sensor includes: a conductive case; a piezoelectric element fixed to a bottom. surface of the case through a conductive adhesive; a temperature compensation capacitor positioned over the piezoelectric element; a first lead wire lead from the outside of the case and electrically connected to one surface of the temperature compensation capacitor and the piezoelectric element; a second lead wire lead from the outside of the case and electrically connected to the other surface of the temperature compensation capacitor and the case; and a first molding part closely adhered to outer portions of the temperature compensation capacitor and the first and second lead wires.

### CROSS REFERENCE TO RELATED APPLICATIONS

This application claims the benefit under 35 U.S.C. Section 119 of Korean Patent Application Serial No. 10-2011-0060743, entitled “ULTRASONIC SENSOR AND METHOD OF MANUFACTURING THE SANE” filed on Jun. 22, 2011, which is hereby incorporated by reference in its entirety into this application.

### BACKGROUND OF THE INVENTION

1. Technical Field

The present invention relates to a sensor, and more particularly, to an ultrasonic sensor used to measure a distance to an object to be measured by generating an ultrasonic wave using a piezoelectric element and sensing a reflected wave, which is an ultrasonic wave reflected from the objected to be measured.

2. Description of the Related Art

As an ultrasonic sensor, two kinds of ultrasonic sensors, that is, a piezoelectricity type of ultrasonic sensor and a magnetostriction type of ultrasonic sensor have been generally used. The piezoelectricity type of ultrasonic sensor uses a phenomenon in which pressure is applied to an object such as a crystal, a PZT (a piezoelectric material), a piezoelectric polymer, and the like, voltage is generated, and when voltage is applied thereto, vibration is generated. The magnetostriction type of ultrasonic sensor uses Joule effect (a phenomenon in which when a magnetic field is applied, vibration is generated) and Villari effect (a phenomenon in which when stress is applied, a magnetic field is generated) generated in an alloy of iron, nickel, and cobalt, and the like.

An ultrasonic element may be an ultrasonic generator simultaneously with being an ultrasonic sensor. The reason is that the piezoelectricity type of ultrasonic sensor senses an ultrasonic wave by voltage generated by applying ultrasonic vibration to a piezoelectric element and generates an ultrasonic wave by vibration generated by applying voltage to the piezoelectric element. In addition, the reason is that the magnetostriction type of ultrasonic sensor generates an ultrasonic wave by the Joule effect and senses an ultrasonic wave by the Villari effect.

A piezoelectricity type of ultrasonic sensor using a piezoelectric element has currently been generally used. The piezoelectricity type of ultrasonic sensor has a structure in which the piezoelectric element is seated in an inner portion of a case and an ultrasonic wave generated in the piezoelectric element is discharged to the outside through the case.

In addition, since the piezoelectric element has sensitivity changed according to an external temperature, a temperature compensation capacitor for compensating for the change in sensitivity is positioned in the inner portion of the case, and a substrate for fixing the temperature compensation capacitor thereto is also mounted in the inner portion of the case. The substrate also serves as a terminal of a wire connecting the piezoelectric element, the temperature compensation capacitor, and the like, to each other.

In addition, a sound absorbing material absorbing vibration energy of the piezoelectric element to thereby reduce a reverberation time and protect internal components is positioned in the inner portion of the case. As the sound absorbing material, a non-woven fabric is used.

The ultrasonic sensor as described above includes various components positioned therein and electrically connected to each other through a wire and a substrate. However, it is difficult to fix these components before being inserted into the case, and the substrate and the temperature compensation capacitor are positioned at positions at which they may not be easily handled in a device, thereby having a difficulty in mass production and automatic production. Due to these problems, most of the ultrasonic sensors have been manually produced.

### SUMMARY OF THE INVENTION

An object of the present invention is to provide an ultrasonic sensor capable of being easily produced automatically and mass-produced by simplifying components through improvement of an internal structure, and a method of manufacturing the same.

According to an exemplary embodiment of the present invention, there is provided an ultrasonic sensor including: a conductive case; a piezoelectric element fixed to a bottom surface of the case through a conductive adhesive; a temperature compensation capacitor positioned over the piezoelectric element; a first lead wire lead from the outside of the case and electrically connected to one surface of the temperature compensation capacitor and the piezoelectric element; a second lead wire lead from the outside of the case and electrically connected to the other surface of the temperature compensation capacitor and the case; and a first molding part closely adhered to outer portions of the temperature compensation capacitor and the first and second lead wires.

The ultrasonic sensor may further include a second molding part positioned between the first molding part and the case to thereby fix the first molding part and the case.

The ultrasonic sensor may further include a sound absorbing material positioned on an upper portion of the piezoelectric element, wherein the sound absorbing material is fixed to the first molding part.

According to another exemplary embodiment of the present invention, there is provided a method of manufacturing an ultrasonic sensor, the method including: bonding a temperature compensation capacitor and first and second lead wires to each other; inserting the temperature compensation capacitor and the first and second lead wires into an inner portion of a mold; forming a first molding part by injecting a molding liquid into the mold; separating the mold and the first molding part from each other when the molding liquid is cured; inserting the first molding part into a case; and bonding the first and second lead wires to the case and a piezoelectric element positioned in an inner portion of the case.

The method may further include forming a second molding part by injecting a molding liquid between the case and the first molding part.

The method may further include positioning a sound absorbing material on an upper portion of the piezoelectric element.

### BRIEF DESCRIPTION OF THE DRAWINGS

FIG. 1 is a perspective view of an ultrasonic sensor according to an exemplary embodiment of the present invention;

FIG. 2 is a cross-sectional view taken along line A-A′ of FIG. 1;

FIG. 3 is a view showing an operation of injecting a molding liquid into a mold; and

FIG. 4 is a view showing an operation of inserting a first molding part into a case.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

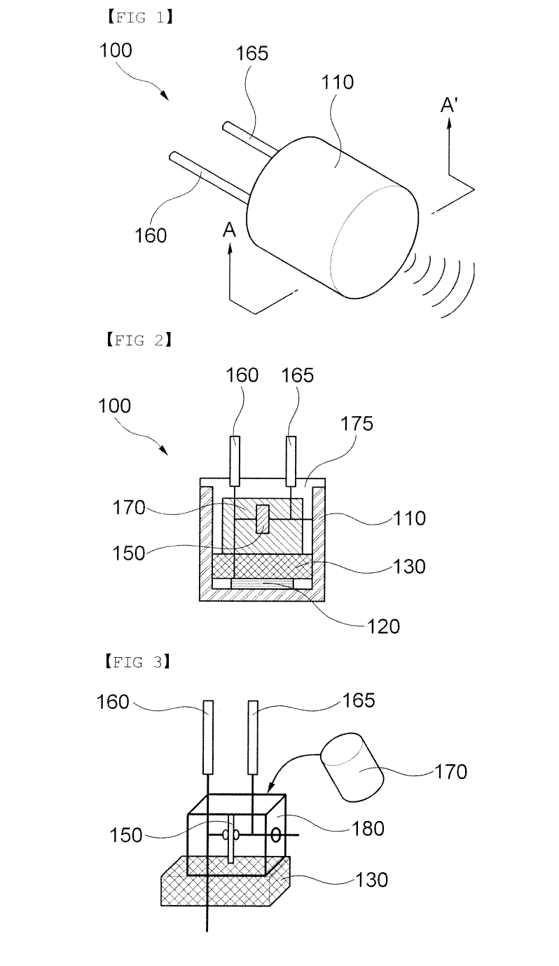

FIG. 1 is a perspective view of an ultrasonic sensor according to an exemplary embodiment of the present invention; and FIG. 2 is a cross-sectional view taken along line A-A′ of FIG. 1. Referring to FIGS. 1 and 2, an ultrasonic sensor 100 according to an embodiment of the present invention includes a case 110, a piezoelectric element 120, a temperature compensation capacitor 150, first and second lead wires 160 and 165, and a first molding part 170.

The case 110 is made of a conductive material and includes a space formed in an inner portion thereof, wherein the space may receive components therein. The piezoelectric element 120 serves to generate an ultrasonic wave and is fixed to a bottom surface of the case 110 through a conductive adhesive.

The piezoelectric element 120, which is a component displaced when a current is applied thereto, is extended or contracted according to polarity of the applied current. Therefore, when the polarity of the current applied to the piezoelectric element 120 is repeatedly changed, the piezoelectric element 120 generates vibration while being repeatedly extended and contracted. An ultrasonic wave is generated from the piezoelectric element 120 through this principle.

Meanwhile, the piezoelectric element 120 has a property in which a capacitance value is changed according to a temperature. Due to this property, reverberation vibration of the piezoelectric element 120 is increased at a low temperature, such that a malfunction of a system is generated, and sensitivity of the piezoelectric element 120 is deteriorated at a high temperature, such that a sensing distance is reduced. In order to prevent this phenomenon, a change in the capacitance value is compensated for by using the temperature compensation capacitor 150.

The first lead wire 160 is lead from the outside of the case 110 and is electrically connected to one surface of the temperature compensation capacitor 150 and an upper surface of the piezoelectric element 120. In addition, the second lead wire 165 is lead from the outside of the case 110 and is electrically connected to the other surface of the temperature compensation capacitor 150 and the case 110.

Since the case 110 is electrically connected to a lower surface of the piezoelectric element 120 through the conductive adhesive, the second lead wire 165 is connected to the lower surface of the piezoelectric element 120 through the case 110.

Meanwhile, the first molding part 170 is formed to have a size at which it may be inserted into the inner portion of the case 110 and is closely adhered to outer portions of the temperature compensation capacitor 150 and the first and second lead wires 160 and 165. That is, the first molding part 170 is formed by filling a molding liquid in the vicinity of the temperature compensation capacitor 150 and the first and second lead wires 160 and 165 and curing the molding liquid.

Therefore, the temperature compensation capacitor 150 and the first and second lead wires 160 and 165 are fixed to the first molding part 170, such that they are modularized as a single component.

As described above, in the ultrasonic sensor 100 according to the exemplary embodiment of the present invention, the temperature compensation capacitor 150 is fixed to the first molding part 170. Therefore, a separate substrate for fixing the temperature compensation capacitor 150 is not required. In addition, the temperature compensation capacitor 150 and the first and second lead wires 160 and 165 are modularized, such that they are simplified as a single component.

According to the related art, at the time of assembly of the ultrasonic sensor 100, a process of individually inserting the respective components into the inner portion of the case 110 and fixing them thereto is required. However, according to the present invention, the above-mentioned process may be replaced by a process of inserting the first molding part 170 into the case 110, thereby making it possible to automatically produce and mass-produce the ultrasonic sensor 100.

In addition, the ultrasonic sensor 100 according to the exemplary embodiment may further include a second molding part 175 fixing the first molding part 170 and the case 110. This second molding part 175 serves to fix the first molding 170 to the case 110 simultaneously with sealing an empty space between the first molding part 170 and the case 110.

In addition, the ultrasonic sensor 100 according to the exemplary embodiment may further include a sound absorbing material 130 positioned on an upper portion of the piezoelectric element 120. This sound absorbing material 130 reduces reverberation which appears after the ultrasonic wave is generated in the piezoelectric element 120.

The piezoelectric element 120 serves to not only generate the ultrasonic wave but also sense an ultrasonic wave reflected and returned from an objected to be measured. The piezoelectric element 120 may sense the reflected ultrasonic wave only when the reverberation that appears after the ultrasonic wave is generated completely disappears.

Therefore, when the reverberation of the piezoelectric element 120 is continued for a long time, it takes a long time to sense the ultrasonic wave, such that it takes a long time for the ultrasonic sensor 100 to sense a distance.

The sound absorbing material 130 serves to reduce the reverberation generated in the piezoelectric element 120 as described above to thereby reduce the sensing time of the ultrasonic sensor 100.

This sound absorbing material 130 is fixed to the first molding part 170. Therefore, the temperature compensation capacitor 150, the first lead wire 160, the second lead wire 165, and the sound absorbing material 130 are modularized as a single component.

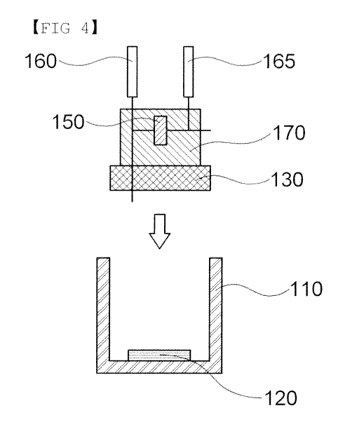

Hereinafter, a method of manufacturing an ultrasonic sensor will be described. FIG. 3 is a view showing an operation of injecting a molding liquid into a mold; and FIG. 4 is a view showing an operation of inserting a first molding part into a case. Referring to FIGS. 3 and 4, a method of manufacturing an ultrasonic sensor according to an exemplary embodiment of the present invention is as follows.

First, a temperature compensation capacitor 150 and first and second lead wires 160 and 165 are bonded and connected to each other. Then, the temperature compensation capacitor 150 and the first and second lead wires 160 and 165 are inserted into an inner portion of a mold 180.

The mold 180 is manufactured to have a size at which it may be inserted into the inner portion of a case 110 and includes the temperature compensation capacitor 150 and the first and second lead wires 160 and 165 inserted into the inner portion thereof as shown in FIG. 3.

Next, a first molding part 170 is formed by injecting a molding liquid into the mold 180. When the injected molding liquid 176 is cured, the first molding part 170 is separated from the mold 180. At this time, the first molding part 170 is cured in a state in which it includes the temperature compensation capacitor 150 and the first and second lead wires 160 and 165, such that the temperature compensation capacitor 150 and the first and second lead wires 160 and 165 are simplified as a single component.

Thereafter, as shown in FIG. 4, the first molding part 170, which is a modularized component of the temperature compensation capacitor 150 and the first and second lead wires 160 and 165, is inserted into the case 110. Then, the first lead wire 160 is bonded to an upper surface of a piezoelectric element 120, and the second lead wire 165 is bonded to the case 110 to thereby complete the ultrasonic sensor 100.

As described above, with the method of manufacturing the ultrasonic sensor according to the exemplary embodiment of the present invention, the temperature compensation capacitor 150 and the first and second lead wires 160 and 165 are modularized to be handled as a single component, such that assembly is easily performed, thereby making it possible to automatically produce and mass produce the ultrasonic sensor.

In addition, the method of manufacturing the ultrasonic sensor according to the exemplary embodiment may further include forming a second molding part 175 by injecting a molding liquid between the case 110 and the first molding part 170. This second molding part 175 serves to seal an empty space between the first molding part 170 and the case 110 simultaneously with fixing the first molding 170 to the case 110.

In addition, the case 110 may further include a sound absorbing material 130 provided in the inner portion thereof. This sound absorbing material 130 is positioned on a lower portion of the first molding part 170 and is attached to the lower portion of the first molding part 170 at the time of curing of the first molding part 170. Therefore, the remaining components except for the piezoelectric element 120 among internal components of the ultrasonic sensor 100 are modularized through the first molding part 170, such that they are simplified as a single component.

As set forth above, with the ultrasonic sensor and the method of manufacturing the same according to the exemplary embodiments of the present invention, a substrate for fixing the temperature compensation capacitor is not required, and the temperature compensation capacitor, the lead wires, the sound absorbing material, and the like, are simplified as a single component, such that assembly is easily performed, thereby making it possible to automatically produce and mass produce the ultrasonic sensor.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. An ultrasonic sensor comprising:
a conductive case;
a piezoelectric element fixed to a bottom surface of the case through a conductive adhesive;
a temperature compensation capacitor positioned over the piezoelectric element;
a first lead wire lead from the outside of the case and electrically connected to one surface of the temperature compensation capacitor and the piezoelectric element;
a second lead wire lead from the outside of the case and electrically connected to the other surface of the temperature compensation capacitor and the case; and
a first molding part closely adhered to outer portions of the temperature compensation capacitor and the first and second lead wires.

2. The ultrasonic sensor according to claim 1, further comprising a second molding part positioned between the first molding part and the case to thereby fix the first molding part and the case.

3. The ultrasonic sensor according to claim 1, further comprising a sound absorbing material positioned on an upper portion of the piezoelectric element, wherein the sound absorbing material is fixed to the first molding part.

4. The ultrasonic sensor according to claim 2, further comprising a sound absorbing material positioned on an upper portion of the piezoelectric element, wherein the sound absorbing material is fixed to the first molding part.

5. A method of manufacturing an ultrasonic sensor, the method comprising:
bonding a temperature compensation capacitor and first and second lead wires to each other;
inserting the temperature compensation capacitor and the first and second lead wires into an inner portion of a mold;
forming a first molding part by injecting a molding liquid into the mold;
separating the mold and the first molding part from each other when the molding liquid is cured;
inserting the first molding part into a case; and
bonding the first and second lead wires to the case and a piezoelectric element positioned in an inner portion of the case.

6. The method according to claim 5, further comprising forming a second molding part by injecting a molding liquid between the case and the first molding part.

7. The method according to claim 5, further comprising positioning a sound absorbing material on an upper portion of the piezoelectric element.

8. The method according to claim 6, further comprising positioning a sound absorbing material on an upper portion of the piezoelectric element.
